(19) United States
(12) Patent Application Publication
(10) Pub. No.: US 2005/0064716 A1
(43) Pub. Date: Mar. 24, 2005

(54) Plasma removal of high k metal oxide

(76) Inventors: Hong Lin, Vancouver, WA (US); Shiqun Gu, Vancouver, WA (US); Wai Lo, Lake Oswego, OR (US); James R.B. Elmer, Vancouver, WA (US)

Correspondence Address: LSI LOGIC CORPORATION, 1621 BARBER LANE, MS: D-106, MILPITAS, CA, 95035, US

(21) Appl. No.: 10/951,646

(22) Filed: Sep. 28, 2004

Related U.S. Application Data
(63) Continuation-in-part of application No. 10/413,051, filed on Apr. 14, 2003.

(51) Int. Cl. H01L 29/80; H01L 31/112; H01L 21/302; H01L 21/461

(52) U.S. Cl. 438/709; 438/710

(57) ABSTRACT

A method of forming a high k gate insulation layer in an integrated circuit on a substrate. A high k layer is deposited onto the substrate, and patterned with a mask to define the high k gate insulation layer and exposed portions of the high k layer. The exposed portions of the high k layer are subjected to an in-situ plasma species that causes structural damage to the exposed portions of the high k layer. The structurally damaged exposed portions of the high k layer are wet etched to leave the high k gate insulation layer.

This application is a continuation in part of copending U.S. patent application Ser. No. 10/413,051 filed Apr. 14, 2004. This invention relates to the field of integrated circuit fabrication. More particularly, this invention relates to improved processes and structures for gate electrode isolation layer formation.

### BACKGROUND

1. Field

Silicon dioxide has typically been used as the dielectric material between the electrically conductive gate electrode, often formed of polysilicon, and the semiconducting channel of a transistor, which is typically formed of silicon. Silicon dioxide has provided adequately high capacitance for gate insulation in the past, with devices having gate geometries of about 130 nanometers and greater. However, with the ever increasing demands of scaled-down device geometries and more densely populated integrated circuits, silicon oxide tends to no longer be good enough for the gate insulation layer.

Current transistor geometries use a gate insulation layer of silicon dioxide that is about twelve to sixteen angstroms thick, or the thickness of about six to ten individual silicon atoms. The silicon dioxide layer gates the electrons through the channel, controlling the flow of electricity across the transistor. However, when the transistor is reduced in size, the silicon dioxide gate insulation layer is also proportionally thinned. As gate lengths decrease from one hundred and thirty nanometers to ninety, sixty-five, and even thirty nanometers, the thickness of the silicon oxide gate will be reduced to less than ten angstroms, or to about three monolayers.

Unfortunately, once the gate insulation layer is reduced to less than about twenty angstroms, the silicon dioxide is no longer able to provide effective insulation from the effects of quantum tunneling currents, and the transistor tends to exhibit relatively high leakage.

Thus, the integrated circuit fabrication industry is searching for gate insulator materials with a low equivalent oxide thickness that mimics the electrical properties of very thin silicon dioxide, while providing a thicker physical layer over the channel to prevent quantum-mechanical tunneling. New materials in the form of oxides of heavy and rare earth metals, with higher dielectric constants and higher capacitances have been investigated with some promising results, including HfSiON, ZrO₂, ZrSiON, HfO₂, HfON, La₂O₃, CeO₂, Na₂O₃, Sm₂O₃, Eu₂O₃, Gd₂O₃, Tb₂O₃, Dy₂O₃, HO₂O₃, Er₂O₃, Tm₂O₃, Yb₂O₃, Lu₂O₃.

However, these so-called high k materials have other problems associated with their use. For example, they do not easily form volatile compounds and are relatively difficult to remove by either dry etching or wet etching. Dry etching has been attempted with ion milling. However, the process can cause extensive damage to the surrounding structures, such as the polysilicon gate electrode, as well as introduce etch defects such as pin-holes and residue high K dielectrics islands. Ion implantation to damage the high k layer followed by selective wet chemical removal of the damaged material has also been attempted, but the efficiency of damage depends on the mass of the implants so that to certain implantation species, such as boron, used for doping silicon substrates, the damage to the dielectrics under the usual CMOS implantation conditions is insufficient, and additional damaging techniques such as nitrogen implantation is needed for ensuring the effective removal of the dielectrics in wet chemicals. For heavier implants such as phosphorous and arsenic, however, there is another risk of displacing the cations in the dielectrics, which will possibly result in the injection of these cations into the substrates since the thickness of the dielectrics is only twenty to sixty angstroms, so that the implant conditions have to be carefully rearranged in order to prevent this from happening.

Although implantation induced wet chemical removal of high k dielectrics is a feasible and verified technique for fabricating high k dielectrics containing devices, there is a need for developing a method whereby such ultra-thin high k materials can be patterned and etched without unduly damaging the surrounding structures that are formed in a conventional CMOS process flow. Preferably, this same technique can also be applied to increasing the removal rate of amorphous high k dielectrics so as to achieve etching selectivity between undamaged materials under the gate electrodes and damaged materials elsewhere.

### SUMMARY

The above and other needs are met by a method of forming a high k gate insulation layer in an integrated circuit on a substrate. A high k layer is deposited onto the substrate, and patterned with a mask to define the high k gate insulation layer and exposed portions of the high k layer. The exposed portions of the high k layer are subjected to an in-situ plasma species that causes structural damage to the exposed portions of the high k layer. The damaged exposed portions of the high k layer are wet etched to leave the high k gate insulation layer.

Because of the relative low kinetic energy (as compared to implantation) and high density of the plasma species, the high K dielectrics, either crystalline or amorphous, can be damaged efficiently yet locally. The structurally damaged high k material etches at a much faster rate than does the undamaged high k material. This process hence advantageously makes use of a local structural damage technique and a wet etch that can proceed at an acceptably high etch rate. In the case of crystalline dielectrics, the higher the degree of crystallinity in the non damaged portions of the high k layer, the greater the etch differential between the non damaged portions of the high k layer and the damaged portions of the high k layer. Further, because the protected high k layer (crystalline or amorphous) is not structurally damaged, the etch is extremely anisotropic, tending only to appreciably remove those portions of the high k layer that have received structural damage, and not undercutting the high k gate insulation layer underlying the masking layer to any appreciable extent.

In various preferred embodiments, the high k layer comprises hafnium dioxide, or alternately at least one of HfSiON, ZrO₂, ZrSiON, HfON, La₂O3, CeO₂, Na₂O₃, Sm₂O₃, Eu₂O₃, Gd₂O₃, Tb₂O₃, Dy₂O₃, Ho₂O₃, Er₂O₃, Tm₂O₃, Yb₂O₃, Lu₂O₃. The plasma contains at least one of nitrogen, argon and other gaseous species. The wet etching is preferably accomplished using a solution of at least one of hydrofluoric acid, piranha, phosphoric acid or other wet chemicals either with or without fluid additives.

In one embodiment there is an additional step of forming a base interface layer on the substrate prior to the step of depositing the high k layer. Preferably, the mask used in the patterning step is a gate electrode layer of sufficient thickness to inhibit penetration of the plasma species through the mask and into the high k gate insulation layer. The mask may also be a gate electrode layer with an overlying hard mask of sufficient combined thickness to inhibit penetration of the plasma species. Further, the mask may be a gate electrode layer with adjacent gate electrode sidewall spacers of sufficient thickness to inhibit penetration of the plasma species through the mask and into the high k gate insulation layer.

According to another aspect of the invention there is described a method of forming a high k gate insulation layer in an integrated circuit on a substrate. A base interface layer is formed on the substrate, and a high k layer of HfSiON or HfO₂ is deposited onto the base interface layer. The high k layer is patterned with a gate electrode layer and an overlying hard mask to define the high k gate insulation layer and exposed portions of the high k layer. The exposed portions of the high k layer are subjected to an in-situ plasma species that causes structural damage to the exposed portions of the high k layer. The damaged exposed portions of the high k layer and the underlying base interface layer are wet etched with at least one of HF, piranha, phosphoric acid or other wet chemicals either with or without fluid additives to leave the high k gate insulation layer.

In various preferred embodiment of this aspect, the in-situ plasma species is preferably inert to the HfSiON and HfO₂, such as at least one of nitrogen and argon.

### BRIEF DESCRIPTION OF THE DRAWINGS

Further advantages of the invention are apparent by reference to the detailed description when considered in conjunction with the figures, which are not to scale so as to more clearly show the details, wherein like reference numbers indicate like elements throughout the several views, and wherein:

FIG. 1 is a cross sectional representation of an integrated circuit with a base interface layer and a high k layer,

FIG. 2 is a cross sectional representation of an integrated circuit with a base interface layer and a high k layer, overlaid with a gate electrode layer and a hard mask layer,

FIG. 3 is a cross sectional representation of an integrated circuit with a base interface layer and a high k layer, overlaid with a patterned gate electrode layer, hard mask layer, and masking layer,

FIG. 4 is a cross sectional representation of an integrated circuit with a base interface layer and a high k layer receiving an plasma species that damages the structure of the high k layer,

FIG. 5 is a cross sectional representation of an integrated circuit with a patterned base interface layer, high k layer, and gate electrode layer,

FIG. 6 is a cross sectional representation of an integrated circuit with a base interface layer and a high k layer, overlaid with a gate electrode layer and adjacent gate electrode sidewall spacers, and

FIG. 7 is a cross sectional representation of an integrated circuit with a patterned base interface layer and high k layer.

### DETAILED DESCRIPTION

As the term is used herein, “integrated circuit” includes devices such as those formed on monolithic semiconducting substrates, such as those formed of group IV materials like silicon or germanium, or group III-V compounds like gallium arsenide, or structured substrate such as silicon-on-insulator, strained silicon and silicon-germanium, or mixtures of such materials. The term includes all types of devices formed, such as memory and logic, and all designs of such devices, such as MOS and bipolar. The term also comprehends applications such as flat panel displays, solar cells, and charge coupled devices.

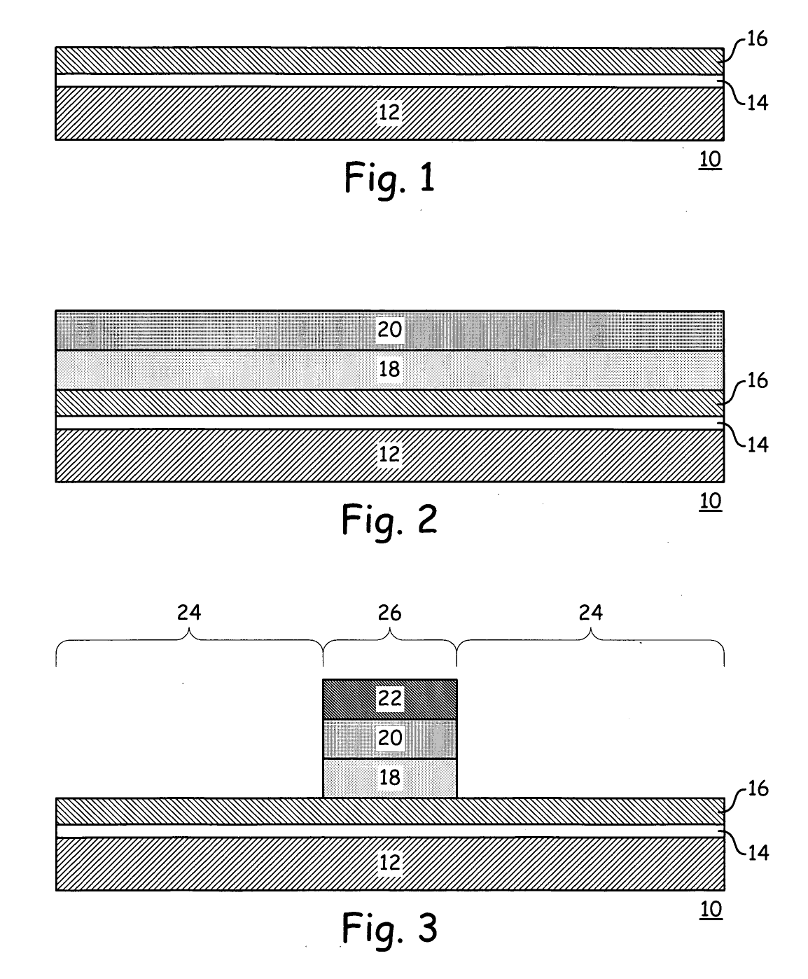

With reference now to FIG. 1, there is depicted a cross sectional representation of an integrated circuit 10 with a base interface layer 14 and a high k layer 16 formed on a base substrate 12. It is appreciated that the dimensions as depicted in the figures are not to scale, so that elements that are very small in comparison to other elements can be seen without undue complication of the figures. It is further appreciated that designation of “substrate” as used herein refers to either or both of the base substrate 12, or all of the layers—including the base substrate 12—on top of which another layer is formed.

In the preferred embodiment the base interface layer 14 is a layer of silicon dioxide having a thickness of between about zero angstroms and about twenty angstroms, or a silicon oxynitride layer. However, the base interface layer 14 is an optional layer, and is not present in some of the embodiments of the invention. The high k layer 16 is preferably formed with a thickness of between about fifteen angstroms and about two hundred angstroms, and is preferably formed of an oxide of a heavy or rare earth metal, including at least one of the materials such as HfSiON, ZrO₂, ZrSiON, HfO₂, HfON, La₂O3, CeO₂, Na₂O₃, Sm₂O₃, Eu₂O₃, Gd₂O₃, Tb₂O₃, Dy₂O₃, HO₂O₃, Er₂O₃, Tm₂O₃, Yb₂O₃, Lu₂O₃. Most preferably, the high k layer 16 is formed of hafnium dioxide or hafnium oxynitride. The dielectric constant of the high k layer 16 is preferably greater than that of silicon dioxide, and most preferably between about twelve and about thirty.

The high k layer 16 is preferably initially formed as an amorphous layer, although depending upon the process used, it may also be initially formed as a crystalline layer. Upon becoming crystalline for certain materials upon further heat treatment, the high k layer 16 become extremely difficult to etch using standard processing. Thus, while the methods described herein are applicable to both amorphous and crystalline high k layers 16, they are especially of value when the high k layer 16 has a high degree of crystal structure prior to etching.

A mask layer is formed over the high k layer 16. As depicted in FIG. 2, the mask layer preferably includes at least a gate electrode layer 18, and may also include an optional hard mask layer 20. The gate electrode layer 18 is preferably formed of polysilicon, and the optional hard mask layer 20 is preferably formed of silicon nitride. A masking layer 22 is applied on top of the mask layer, such as on top of the gate electrode layer 18 and the optional hard mask layer 20. The masking layer 22 is preferably a photoresist. The masking layer 22 is then patterned and used to etch the pattern into the underlying mask layer, as depicted in FIG. 3.

As seen in FIG. 3, the etching process used to define the mask layer, which in this case is a gate electrode layer 18 and optional hard mask layer 20, does not etch the high k layer 16, because the high k layer 16 tends to be extremely resistive to etching, as described above. Therefore, the high k layer 16 tends to provide an excellent etch stop to the etching process used to define the mask layer 18 and 20. The patterned mask layer 18 and 20 also defines a high k gate insulation layer region 26, which underlies the mask layer 18 and 20, and exposed portions 24 of the high k layer 16. Once the etching of the mask layer 18 and 20 is accomplished, the masking layer 22 is preferably removed, such as in an ashing process.

The exposed portions 24 of the high k layer 16 are subjected to a low energy in-situ plasma of a species 28 that causes a controlled degree of structural damage to the exposed portions 24 of the high k layer 16, as depicted in FIG. 4. However, the overlying mask layer 18 and 20, and optionally 22, prohibit the in-situ plasma 28 from contacting and damaging the high k layer 16 in the region 26. In a preferred embodiment, the in-situ plasma 28 is a species that is relatively inert to the high k layer 16, such as nitrogen or argon, but which is of sufficient mass, or is used to form a plasma of sufficient energy, so as to cause some degree of structural damage to the exposed portions 24 of the high k layer 16. Other plasma species 28 may also be used.

It is appreciated that exposure of the high k layer 16 to the plasma species 28 is not extended for too great a length of time. For example, it is not the intent to etch the high k layer 16 with the plasma species 28 to any appreciable degree at all, either by length of time of the plasma 28 or energy of the plasma 28. Because of the resiliency of the high k layer 16 to a plasma that is intended to etch the high k layer 16, exposure for such a length of time to cause an appreciable etch of the high k layer 16 would tend to cause substantial damage to the other structures of the integrated circuit 10. Thus, the exposure to the plasma 28 is preferably limited to an amount of time that is just sufficient to damage the structure of the high k layer 16, without causing any appreciable etching of the high k layer 16 or appreciable damage to the other structures of the integrated circuit 10.

Once the structural damage has been caused to the exposed portions 24 of the high k layer 16, the exposed portions 24 of the high k layer 16 can be etched relatively easily, as compared to those portions 26 of the high k layer 16 that have not sustained damage. Most preferably the etching process is a wet etch using a solution of at least one of hydrofluoric acid, piranha, phosphoric acid and other wet chemicals either with or without fluid additives. As these etchants are relatively selective as to the underlying base substrate 12, substantially all of the exposed portion 24 of the high k layer 16 and underlying portions of the base interface layer 14, if present, are removed during the etch process, but the underlying base substrate 12 is not damaged to any appreciable degree by the etch process.

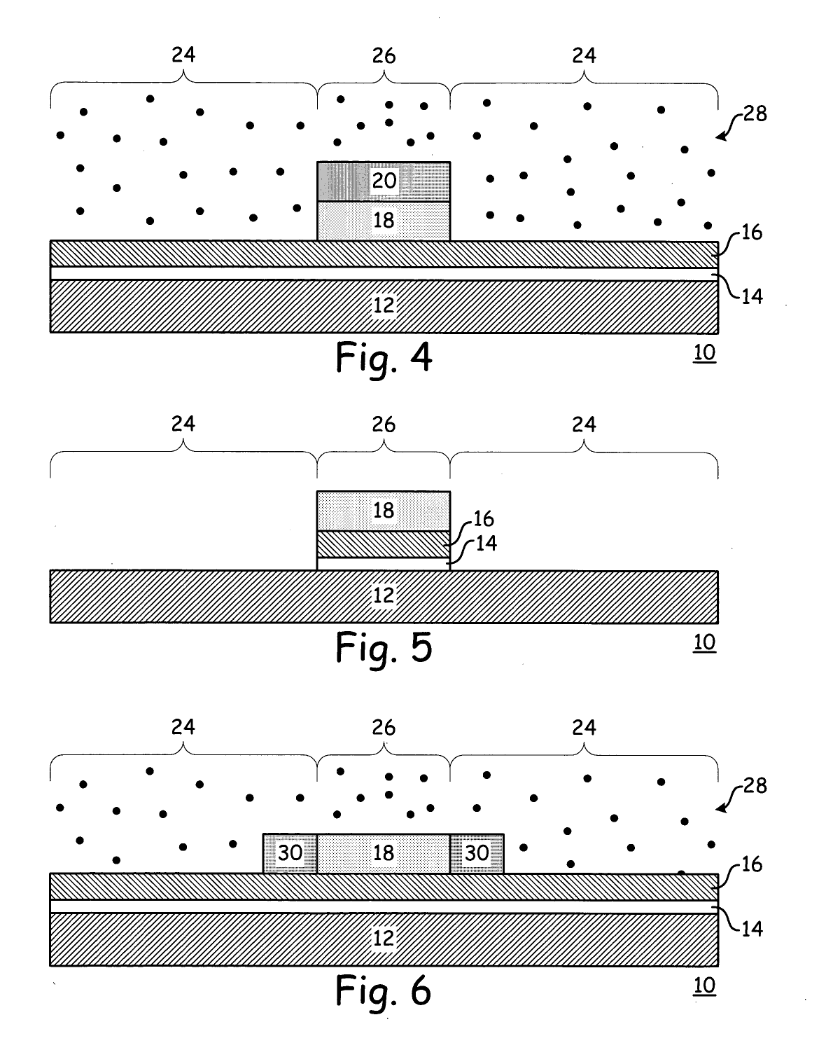

In addition, some of these etchants tend to remove the photoresist mask 22, if it has not previously been removed, and also remove any polymer residue that may have been formed by the plasma 28 from the photoresist mask 22, if it was present during the in-situ plasma 28. In the case where the etchants do not remove the photoresist mask, additional steps can be used for removing the mask as well as cleaning the surfaces of the subsequent structures. The resultant structure is depicted in FIG. 5. At this point, subsequent processing is accomplished, such as according to the desired and normal CMOS process flows.

Because the protected and undamaged portion 26 of the high k layer 16 does not etch at an appreciable rate, or at least etches at a rate that is dramatically less than the rate at which the structurally damaged portion 24 of the high k layer 16 etches, the etching process, even though preferably accomplished as a wet etch, is substantially anisotropic. In other words, the etching process does not undercut the high k layer 16 in the protected regions 26 to any substantial degree, because the etch rate of the high k layer 16 in the protected regions 26 is so low.

The in-situ plasma exposure of the portions 24 of the high k layer 16 can be accomplished in a standard process flow of the integrated circuit 10, as next described. In this embodiment, the gate electrode layer 18 is deposited, patterned, and formed, and oxide sidewall spacers 30 are also deposited, patterned, and formed. The gate electrode layer 18 and the oxide sidewall spacers 30 then constitute the mask which is used to protect the region 26 of the high k layer 16, as depicted in FIG. 6.

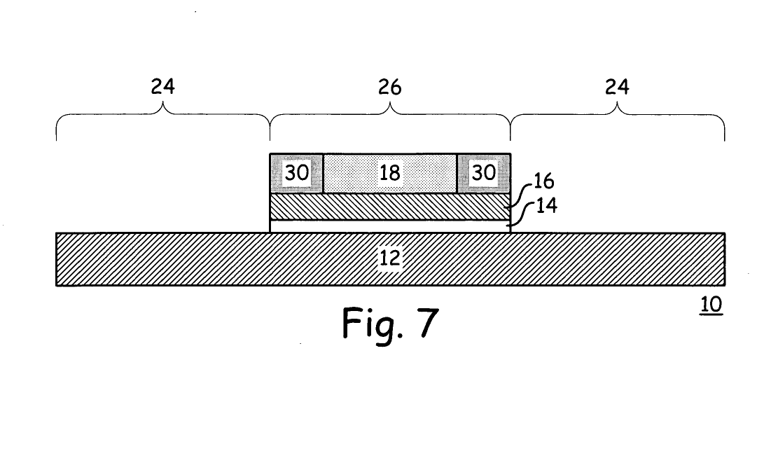

As before, the mask 18 and 30 is preferably of a sufficient thickness to prohibit the plasma species from contacting the protected region 26 of the high k layer 16. An optional hard mask or photoresist mask can be added as desired over the mask 18 and 30. Once the damage caused by the in-situ plasma 28 is sustained in the exposed portions 24 of the high k layer 16, those portions 24 can be removed, such as with the wet etch as described above. The resultant structure is depicted in FIG. 7.

However, in either of the general processing flows described above, the use of an in-situ plasma to damage the structure of the exposed portions 24 of the high k layer 16 allows the high k layer 16 to be adequately etched, such as in at least one of an aqueous hydrofluoric acid solution, piranha, phosphoric acid or other wet chemicals either with or without fluid additives, while neither the underlying base substrate 12 or the protected portion 26 of the high k layer 16 are appreciably etched or damaged.

The present invention is highly beneficial, because the energy of the nitrogen or argon ions can be actively controlled, thus minimizing any excessively high ion energy ion sputtering etch effect, which in turn reduces the substrate surface damage. The absence of very high ion energy (such as that characteristic of ion implantation) also avoids damaging the substrate or injecting ions into the substrate under the dielectrics. The present invention also uses conventional wet chemicals to selectively remove the structurally damaged high k material. An inert gas is preferably used as the plasma species, to prevent direct reactive ion etching of the gate electrode, pattern resist, and high k material, and also so as to prevent substrate oxidation that may cause recesses.

The foregoing description of preferred embodiments for this invention has been presented for purposes of illustration and description. It is not intended to be exhaustive or to limit the invention to the precise form disclosed. Obvious modifications or variations are possible in light of the above teachings. The embodiments are chosen and described in an effort to provide the best illustrations of the principles of the invention and its practical application, and to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

1. A method of forming a high k gate insulation layer in an integrated circuit on a substrate, the method comprising the steps of:
depositing a high k layer onto the substrate,
patterning the high k layer with a mask to define the high k gate insulation layer and exposed portions of the high k layer,
subjecting the exposed portions of the high k layer to an in-situ plasma species that causes structural damage to the exposed portions of the high k layer, and
wet etching the damaged exposed portions of the high k layer to leave the high k gate insulation layer.

2. The method of claim 1, wherein the high k layer comprises hafnium dioxide.

3. The method of claim 1, wherein the high k layer comprises at least one of HfSiON, ZrO₂, ZrSiON, HfON, La₂O3, CeO₂, Na₂O₃, Sm₂O₃, Eu₂O₃, Gd₂O₃, Tb₂O₃, Dy₂O₃, HO₂O₃, Er₂O₃, Tm₂O₃, Yb₂O₃, Lu₂O₃.

4. The method of claim 1, wherein the in-situ plasma species comprises at least one of nitrogen and argon.

5. The method of claim 1, wherein an energy of the in-situ plasma is sufficient to structurally damage the high k gate insulation layer.

6. The method of claim 1, wherein an energy of the in-situ plasma is not high enough to cause significant sputtering of the high k gate insulation layer, damage to the underlying substrate, and injection of ions of the high k gate insulation layer into the substrate.

7. The method of claim 1, wherein a treatment time of the in-situ plasma is long enough to cause structural damage in the high k gate insulation layer.

8. The method of claim 1, wherein a treatment time of the in-situ plasma is not long enough to cause significant sputtering of the high k gate insulation layer.

9. The method of claim 1, wherein the etching is a wet etch using a solution of hydrofluoric acid.

10. The method of claim 1, wherein the wet etching is accomplished using a solution of piranha.

11. The method of claim 1, wherein the wet etching is accomplished using a solution of phosphoric acid.

12. The method of claim 1, wherein the wet etching is accomplished using a wet chemical with fluid additives.

13. The method of claim 1, further comprising the step of forming a base interface layer on the substrate prior to the step of depositing the high k layer.

14. The method of claim 1, wherein the mask used in the patterning step is a gate electrode layer sufficient to inhibit penetration of the plasma species through the mask and into the high k gate insulation layer.

15. The method of claim 1, wherein the mask used in the patterning step is a gate electrode layer with an overlying hard mask sufficient to inhibit penetration of the plasma species through the mask and into the high k gate insulation layer.

16. The method of claim 1, wherein the mask used in the patterning step is a gate electrode layer with adjacent gate electrode sidewall spacers sufficient to inhibit penetration of the plasma species through the mask and into the high k gate insulation layer.

17. A method of forming a high k gate insulation layer in an integrated circuit on a substrate, the method comprising the steps of:
forming a base interface layer on the substrate,
depositing a high k layer of HfSiON or HfO₂ onto the base interface layer,
patterning the high k layer with a gate electrode layer and an overlying hard mask to define the high k gate insulation layer and exposed portions of the high k layer,
subjecting the exposed portions of the high k layer to an in-situ plasma species that causes structural damage to the exposed portions of the high k layer, and
wet etching the damaged exposed portions of the high k layer and the underlying base interface layer with at least one of HF and piranha to leave the high k gate insulation layer.

18. The method of claim 17, wherein the in-situ plasma species comprises a species that is inert to HfSiON or HfO₂, such as at least one of nitrogen and argon.
